(19) United States
(12) Patent Application Publication
(10) Pub. No.: US 2025/0370295 A1
(43) Pub. Date: Dec. 4, 2025

(54) DISPLAY APPARATUS

(71) Applicant: SAMSUNG ELECTRONICS CO., LTD., Suwon-si (KR)

(72) Inventors: Soonjung KIM, Suwon-si (KR); Naewon JANG, Suwon-si (KR)

(73) Assignee: SAMSUNG ELECTRONICS CO., LTD., Suwon-si (KR)

(21) Appl. No.: 19/299,964

(22) Filed: Aug. 14, 2025

Related U.S. Application Data
(63) Continuation of application No. PCT/KR2024/000320, filed on Jan. 8, 2024.

(30) Foreign Application Priority Data
Feb. 28, 2023 (KR) 10-2023-0027153

(51) Int. Cl. G02F 1/13357; G02F 1/1335

(52) U.S. Cl. CPC G02F 1/133603; G02F 1/133605; G02F 1/133607; G02F 1/133614

(57) ABSTRACT

This display apparatus includes a liquid crystal panel; and a backlight configured to provide light to the liquid crystal panel, wherein the backlight comprises: a substrate; a light emitting diode provided on the substrate, the light emitting diode comprising a light output layer having a first refractive index, r1; a refractive layer covering the light emitting diode and having a second refractive index, r2, that is lower than the first refractive index; and a quantum dot layer covering the refractive layer, configured to convert a wavelength of light emitted from the light emitting diode, the quantum dot layer having a third refractive index, r3, that is lower than the second refractive index.

### CROSS-REFERENCE TO RELATED APPLICATION(S)

This application is a continuation of International Application No. PCT/KR2024/000320, filed on Jan. 8, 2024, in the Korean Intellectual Property Receiving Office, which claims priority to Korean Patent Application No. 10-2023-0027153, filed on Feb. 28, 2023, in the Korean Intellectual Property Office, the disclosures of which are incorporated by reference herein in their entireties.

### BACKGROUND

### 1. Field

The disclosure relates to a display apparatus including a backlight unit.

### 2. Description of Related Art

Generally, a display apparatus is a kind of an output apparatus that converts obtained or stored electrical information into visual information and displays the visual information to a user, and is used in various fields such as a home and a business place.

The display apparatus includes a monitor apparatus connected to a personal computer or a server computer, a portable computer apparatus, a navigation terminal apparatus, a general television apparatus, an Internet Protocol television (IPTV) apparatus, a portable terminal apparatus such as a smart phone, a tablet PC, a personal digital assistant (PDA) or a cellular phone, various display apparatuses used to reproduce images such as advertisements or movies in an industrial field, or various kinds of audio/video systems.

Display apparatus may include a liquid crystal panel and a backlight unit (BLU) that provides light to the liquid crystal panel. The backlight unit may include a plurality of light sources that may independently emit light.

### SUMMARY

An aspect of the disclosure provides a backlight unit including a light source with improved light output efficiency, and a display apparatus including the same.

The technical objectives of the disclosure are not limited to the above, and other objectives that are not described above will be clearly understood by those skilled in the art from the above detailed description.

According to an aspect of the disclosure, there is provided a display apparatus including: a liquid crystal panel; and a backlight configured to provide light to the liquid crystal panel, wherein the backlight includes: a substrate; a light emitting diode provided on the substrate, the light emitting diode including a light output layer having a first refractive index, r1; a refractive layer covering the light emitting diode and having a second refractive index, r2, that is lower than the first refractive index; and a quantum dot layer covering the refractive layer, configured to convert a wavelength of light emitted from the light emitting diode, the quantum dot layer having a third refractive index, r3, that is lower than the second refractive index.

The third refractive index of the quantum dot layer may be greater than 1.

The second refractive index may be r1−(r1−1)/3±0.3.

The third refractive index may be r1−(r1−1)*2/3±0.3.

The refractive layer may be a first refractive layer, further including: a second refractive layer covering the quantum dot layer and having a fourth refractive index, r4, that is lower than the third refractive index.

The second refractive index may be r1−(r1−1)/4±0.3.

The third refractive index may be r1−(r1−1)*2/4±0.3.

The fourth refractive index may be r1−(r1−1)*3/4±0.3.

The quantum dot layer may include: a resin including at least one of acrylic, silicone, epoxy, or urethane; and a plurality of quantum dot particles dispersed within the resin.

Each of the plurality of quantum dot particles may include a quantum dot and a quantum dot coating layer surrounding the quantum dot, wherein the quantum dot coating layer includes at least one of SiO₂, Al₂O₃, or HfO₂.

A thickness of the quantum dot coating layer may be 1 nm to 1 μm.

The refractive layer may include at least one of acrylic, silicone, epoxy, or urethane.

The light output layer of the light emitting diode may be a transparent substrate of the light emitting diode or a reflective layer provided on the transparent substrate.

The light emitting diode may be provided on the substrate in a chip-on-board manner.

### BRIEF DESCRIPTION OF THE DRAWINGS

The above and other aspects and/or features of embodiments of the disclosure will be more apparent from the following description taken in conjunction with the accompanying drawings, in which:

FIG. 1 is a perspective view of a display apparatus according to an embodiment;

FIG. 2 is an exploded perspective view of a display apparatus according to an embodiment;

FIG. 3 is a side cross-sectional view of a liquid crystal panel in a display apparatus according to an embodiment;

FIG. 4 is an exploded perspective view of a backlight unit in a display apparatus according to an embodiment;

FIG. 5 schematically illustrates an example of a light source in a display apparatus according to an embodiment;

FIG. 6 illustrates a cross-section of an example of a light emitting diode in a display apparatus according to an embodiment;

FIG. 7 illustrates an example of a cross-section taken along line A-A′ of FIG. 5;

FIG. 8 illustrates an enlarged view of part B of FIG. 7;

FIG. 9 illustrates an example of a cross-section taken along line A-A′ of FIG. 5;

FIG. 10 illustrates an example of a cross-section taken along line A-A′ of FIG. 5; and

FIG. 11 illustrates a cross-section of an example of a light emitting diode in a display apparatus according to an embodiment.

### DETAILED DESCRIPTION

Various embodiments of the present document and terms used therein are not intended to limit the technical features described in this document to specific embodiments, and should be understood to include various modifications, equivalents, or substitutes of the corresponding embodiments. In connection with the description of the drawings, similar reference numerals may be used for similar or related components.

The singular form of a noun corresponding to an item may include one or a plurality of the items unless clearly indicated otherwise in a related context.

In this document, phrases, such as “A or B”, “at least one of A and B”, “at least one of A or B,” “A, B or C,” “at least one of A, B and C,” and “at least one of A, B, or C”, may include any one or all possible combinations of items listed together in the corresponding phrase among the phrases.

As used herein, the term “and/or” includes any and all combinations of one or more of associated listed items.

Terms, such as “1st”, “2nd”, “primary”, or “secondary” may be used simply to distinguish a component from other components, without limiting the component in other aspects (e.g., importance or order).

When one (e.g., a first) element is referred to as being “coupled” or “connected” to another (e.g., a second) element with or without the term “functionally” or “communicatively,” it means that the one element is connected to the other element directly, wirelessly, or via a third element.

It will be understood that when the terms “includes,” “comprises,” “including,” and/or “comprising,” when used in this specification, specify the presence of stated features, FIGS., steps, operations, components, members, or combinations thereof, but do not preclude the presence or addition of one or more other features, FIGS., steps, operations, components, members, or combinations thereof.

It will be understood that when a certain component is referred to as being “connected to”, “coupled to”, “supported by” or “in contact with” another component, it may be directly or indirectly connected to, coupled to, supported by, or in contact with the other component. When a component is indirectly connected to, coupled to, supported by, or in contact with another component, it may be connected to, coupled to, supported by, or in contact with the other component through a third component.

It will also be understood that when a component is referred to as being “on” another component, it may be directly on the other component or intervening components may also be present.

Further, as used in the disclosure, the terms “front”, “rear”, “top”, “bottom”, “side”, “left”, “right”, “upper”, “lower”, and the like are defined with reference to the drawings, and are not intended to limit the shape and position of each component.

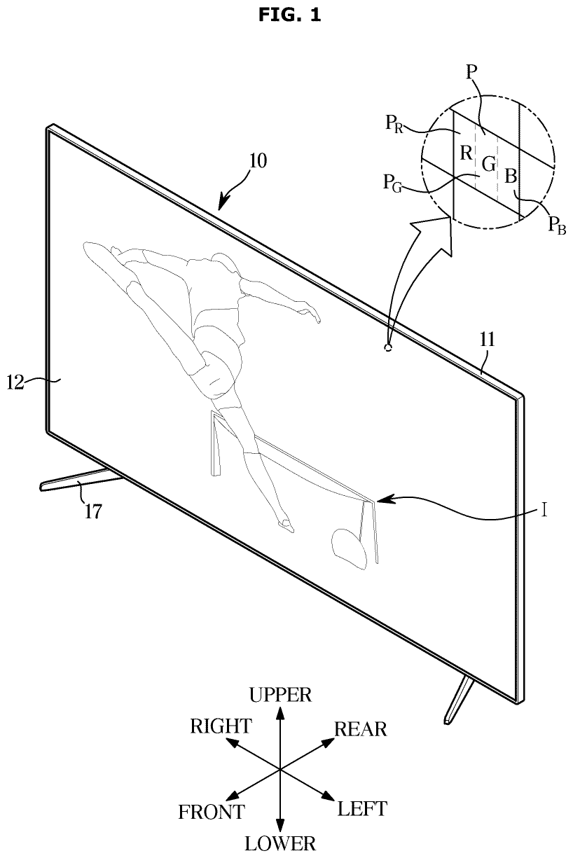

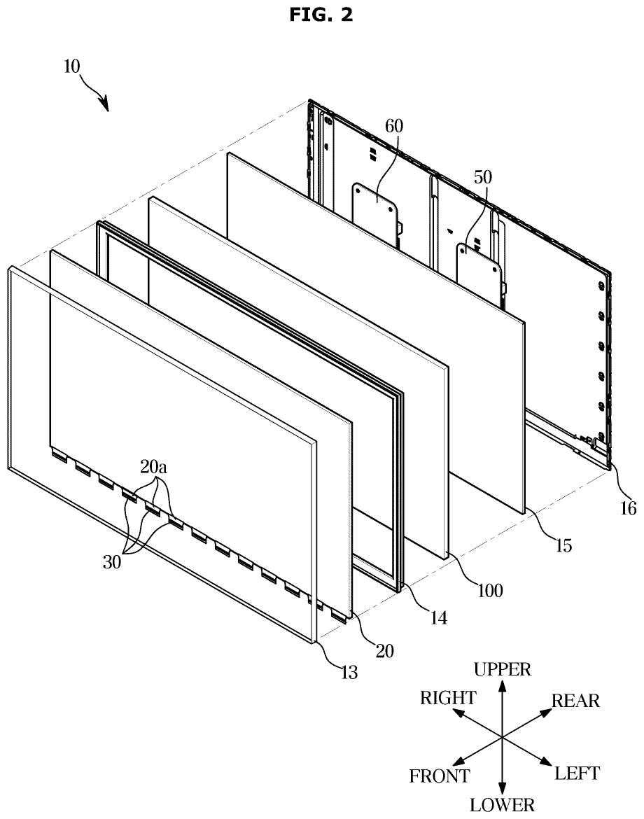

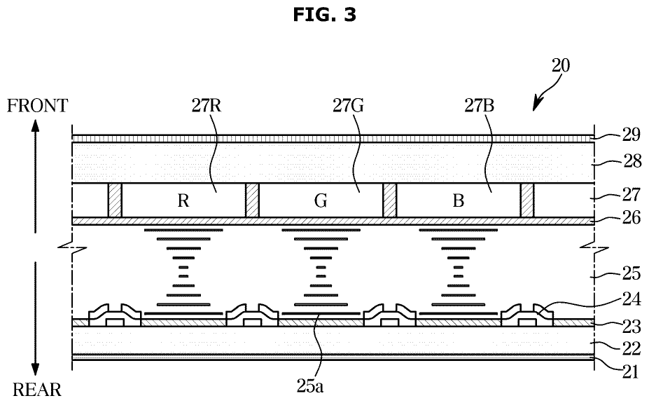

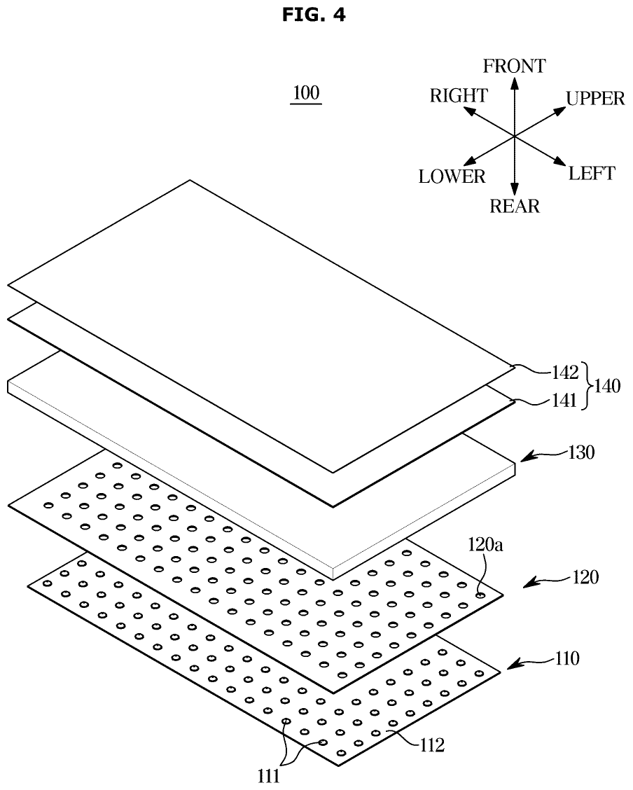

FIG. 1 is a perspective view of a display apparatus according to an embodiment. FIG. 2 is an exploded perspective view of a display apparatus according to an embodiment. FIG. 3 is a side cross-sectional view of a liquid crystal panel in a display apparatus according to an embodiment. FIG. 4 is an exploded perspective view of a backlight unit in a display apparatus according to an embodiment.

FIG. 1 is a view illustrating an exterior of a display apparatus according to an embodiment.

A display apparatus 10 is an apparatus that may process an image signal received from the outside and visually display the processed image. Hereinafter, a case in which the display apparatus 10 is a television (TV) is exemplified, but the disclosure is not limited thereto. For example, the display apparatus 10 may be implemented in various forms such as a monitor, a portable multimedia apparatus, and a portable communication apparatus, and the display apparatus 10 is not limited in its form as long as the display apparatus visually displays an image.

In addition, the display apparatus 10 may be a large format display (LFD) installed outdoors, such as on a roof of a building or at a bus stop. Here, the outdoors is not necessarily limited to the outdoors, and the display apparatus 10 according to an embodiment may be installed wherever a large number of people may enter and exit, even indoors such as at subway stations, shopping malls, movie theaters, companies, and stores.

The display apparatus 10 may receive content data including video data and audio data from various content sources and output video and audio corresponding to the video data and audio data. For example, the display apparatus 10 may receive content data through a broadcast reception antenna or a wired cable, receive content data from a content playback apparatus, or receive content data from a content-providing server of a content provider.

As shown in FIG. 1, the display apparatus 10 includes a body 11, a screen 12 displaying an image I, and a support 17 provided below the body 11 to support the body 10.

The body 11 may form the exterior of the display apparatus 10, and the body 11 may include a component configured to allow the display apparatus 10 to display the image I or a component configured to perform various functions. The body 11 shown in FIG. 1 has a flat plate shape, but the shape of the body 11 is not limited to that shown in FIG. 1. For example, the body 11 may have a curved plate shape.

The screen 12 may be formed on a front surface of the body 11 and may display the image I. For example, the screen 12 may display a still image or a video. In addition, the screen 12 may display a two-dimensional plane image or a three-dimensional stereoscopic image using binocular parallax of a user.

A plurality of pixels P may be formed on the screen 12, and the image I displayed on the screen 12 may be formed by light emitted from each of the plurality of pixels P. For example, the image I may be formed on the screen 12 by combining light emitted from the plurality of pixels P like a mosaic.

Each of the plurality of pixels P may emit light of various brightness and various colors. For example, each of the plurality of pixels P may include a non-self-luminous panel (e.g., a liquid crystal panel) that may transmit or block light emitted by a light source device or the like.

In order to emit light of various colors, each of the plurality of pixels P may include sub-pixels PR, PG, and PB.

The sub-pixels PR, PG, and PB may include a red sub-pixel PR capable of emitting red light, a green sub-pixel PG capable of emitting green light, and a blue sub-pixel PB capable of emitting blue light. For example, the red light may represent light having a wavelength of approximately 620 nm (nanometers, one billionth of a meter) to 750 nm, the green light may represent light having a wavelength of approximately 495 nm to 570 nm, and the blue light may represent light having a wavelength of approximately 430 nm to 495 nm.

By combining the red light of the red sub-pixel PR, the green light of the green sub-pixel PG, and the blue light of the blue sub-pixel PB, each of the plurality of pixels P may emit light of various brightness and various colors.

As shown in FIG. 2, various components for generating the image (I in FIG. 1 on the screen 12 in FIG. 1 may be provided in the body 11.

For example, the body 11 includes a backlight unit 100 which is a surface light source, a liquid crystal panel 20 configured to block or transmit light emitted from the backlight unit 100, a control assembly 50 configured to control operations of the backlight unit 100 and the liquid crystal panel 20, and a power supply assembly 60 configured to supply power to the backlight unit 100 and the liquid crystal panel 20. In addition, the body 11 includes a bezel 13, a frame middle mold 14, a bottom chassis 15, and a rear cover 16 for supporting and fixing the liquid crystal panel 20, the backlight unit 100, the control assembly 50, and the power supply assembly 60. Alternatively, the bezel and the frame middle mold may be provided as one part.

The backlight unit 100 may include a point light source that emits monochromatic light or white light, and may refract, reflect, and scatter the light to convert the light emitted from the point light source into a uniform surface light. For example, the backlight unit 100 may include a plurality of light sources configured to emit the monochromatic light or white light, a diffuser plate configured to diffuse the light incident from the plurality of light sources, a reflective sheet configured to reflect the light emitted from a rear surface of the diffuser plate and the plurality of light sources, and an optical sheet configured to refract and scatter the light emitted from a front surface of the diffuser plate.

As such, the backlight unit 100 may emit a uniform surface light toward the front by refracting, reflecting, and scattering the light emitted from the light source.

The configuration of the backlight unit 100 will be described in more detail below.

The liquid crystal panel 20 is provided in front of the backlight unit 100, and blocks or transmits light emitted from the backlight unit 100 to form the image I.

A front surface of the liquid crystal panel 20 may form the screen 12 of the display apparatus 10 described above, and the liquid crystal panel 20 may include the plurality of pixels P. The plurality of pixels P included in the liquid crystal panel 20 may independently block or transmit the light emitted from the backlight unit 100, and the light transmitted by the plurality of pixels P may form the image I to be displayed on the screen 12.

For example, as shown in FIG. 3, the liquid crystal panel 20 may include a first polarizing film 21, a first transparent substrate 22, a pixel electrode 23, a thin-film transistor (TFT) 24, a liquid crystal layer 25, a common electrode 26, a color filter 27, a second transparent substrate 28, and a second polarizing film 29.

The first transparent substrate 22 and the second transparent substrate 28 may fixedly support the pixel electrode 23, the thin-film transistor 24, the liquid crystal layer 25, the common electrode 26, and the color filter 27. The first and second transparent substrates 22 and 28 may be formed of tempered glass or transparent resin.

The first polarizing film 21 and the second polarizing film 29 are provided on outer sides of the first and second transparent substrates 22 and 28, respectively.

The first polarizing film 21 and the second polarizing film 29 may transmit specific light and block reflect or absorb the other light, respectively. For example, the first polarizing film 21 may transmit light having a magnetic field oscillating in a first direction and block reflect or absorb other light. In addition, the second polarizing film 29 may transmit light having a magnetic field oscillating in a second direction and block reflect or absorb other light. In this case, the first direction and the second direction may be perpendicular to each other. Accordingly, the polarization direction of light transmitted through the first polarizing film 21 and the oscillation direction of light transmitted through the second polarizing film 29 are perpendicular to each other. As a result, light generally may not pass through both the first polarizing film 21 and the second polarizing film 29 simultaneously.

The color filter 27 may be provided on an inner side of the second transparent substrate 28.

The color filter 27 may include a red filter 27R configured to transmit red light, a green filter 27G configured to transmit green light, and a blue filter 27B configured to transmit blue light. In addition, the red filter 27R, the green filter 27G, and the blue filter 27B may be disposed parallel to each other. A region in which the color filter 27 is formed corresponds to the pixel P described above. A region in which the red filter 27R is formed corresponds to the red sub-pixel PR, a region in which the green filter 27G is formed corresponds to the green sub-pixel PG, and a region in which the blue filter 27B is formed corresponds to the blue sub-pixel PB.

The pixel electrode 23 may be provided on an inner side of the first transparent substrate 22, and the common electrode 26 may be provided on the inner side of the second transparent substrate 28.

The pixel electrode 23 and the common electrode 26 are formed of a metal material through which electricity is conducted and may generate an electric field for changing the arrangement of liquid crystal molecules 115a constituting the liquid crystal layer 25 to be described below.

The pixel electrode 23 and the common electrode 26 may be composed of a transparent material, and may allow light incident from the outside to pass therethrough. For example, the pixel electrode 23 and the common electrode 26 may be composed of indium tin oxide (ITO), indium zinc oxide (IZO), a silver nanowire (Ag nanowire), a carbon nanotube (CNT), graphene, poly3,4-ethylenedioxythiophene) (PEDOT), or the like.

The thin-film transistor 24 is provided on the inner side of the first transparent substrate 22.

The thin film transistor 24 may allow or block the current flowing to the pixel electrode 23. For example, by turning the thin-film transistor 24 on (closing) or off (opening), an electric field may be formed or removed from between the pixel electrode 23 and the common electrode 26.

The thin film transistor 24 may be composed of poly-silicon, and may be formed by semiconductor processes such as a lithography process, a deposition process, an ion implantation process, and the like.

The liquid crystal layer 25 is formed between the pixel electrode 23 and the common electrode 26. The liquid crystal layer 25 is filled with liquid crystal molecules 25a.

A liquid crystal indicates an intermediate state between a solid (crystal) and a liquid. Most of the liquid crystal materials are organic compounds, their molecular shape is a long and thin rod, and may have a crystal form in which the arrangement of the molecules is irregular in any direction, but is regular in another direction. As a result, the liquid crystal has both fluidity of the liquid and optical anisotropy of the crystal (solid).

Further, the liquid crystal also exhibits optical properties according to a change in electric field. For example, in the liquid crystal, the direction of the arrangement of molecules constituting the liquid crystal may be changed according to the change in electric field. When the electric field is generated in the liquid crystal layer 25, the liquid crystal molecules 25a of the liquid crystal layer 25 are arranged according to the direction of the electric field, and when the electric field is not generated in the liquid crystal layer 25, the liquid crystal molecules 25a may be irregularly arranged or may be arranged along an alignment layer. As a result, the optical properties of the liquid crystal layer 25 may be changed according to the presence or absence of the electric field passing through the liquid crystal layer 25.

A cable 20a through which image data is transmitted to the liquid crystal panel 20 and a display driver integrated circuit (DDI) 30 (hereinafter, referred to as the “driver IC”) configured to process digital image data and output an analog image signal are provided on one side of the liquid crystal panel 20.

The cable 20a may electrically connect between the control assembly 50 and the power supply assembly 60 and the driver IC 30 and may also electrically connect between the driver IC 30 and the liquid crystal panel 20. The cable 20a may include a flexible flat cable, a film cable, or the like that may be bendable.

The driver IC 30 may receive image data and power from the control assembly 50 and the power supply assembly 60 through the cable 20a. Further, the driver IC 30 may provide image data and driving current to the liquid crystal panel 20 through the cable 20a.

Further, the cable 20a and the driver IC 30 may be integrally implemented as a film cable, a chip-on-film (COF), a tape carrier package (TCP), or the like. In other words, the driver IC 30 may be disposed on the cable 20a. However, the disclosure is not limited thereto, and the driver IC 30 may be disposed on the liquid crystal panel 20.

The control assembly 50 may include a control circuit configured to control operations of the liquid crystal panel 20 and the backlight unit 100. The control circuit may process image data received from an external content source, transmit the image data to the liquid crystal panel 20, and transmit dimming data to the backlight unit 100.

The power assembly 60 may supply power to the liquid crystal panel 20 and the backlight unit 100 such that the backlight unit 100 outputs planar light and the liquid crystal panel 20 blocks or transmits the light from the backlight unit 100.

The control assembly 50 and the power supply assembly 60 may be implemented with a printed circuit board and various circuits mounted (e.g., provided) on the printed circuit board. For example, the power supply circuit may include a condenser, a coil, a resistance element, a processor, and the like and a power supply circuit board on which these elements are mounted. In addition, the control circuit may include a memory, a processor, and a control circuit board on which these elements are mounted.

Hereinafter, the backlight unit 100 will be described.

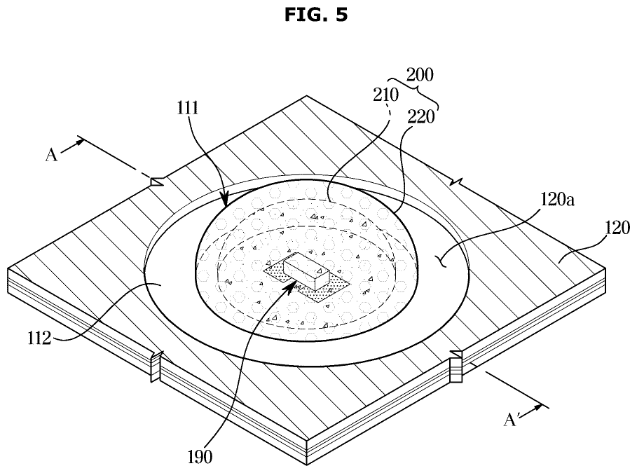

Referring to FIG. 5, the backlight unit 100 includes a light source module 110 configured to generate light, a reflective sheet 120 configured to reflect the light, a diffuser plate 130 configured to uniformly diffuse the light, and an optical sheet 140 configured to improve brightness of the emitted light.

The light source module 110 may include a plurality of light sources 111 configured to emit light and substrates 112 configured to support and fix the plurality of light sources 111.

The plurality of light sources 111 may be disposed in a predetermined pattern to allow the emitted light to have uniform brightness. The plurality of light sources 111 may be disposed such that intervals between one light source and the light sources adjacent thereto become equal to each other.

For example, as shown in FIG. 4, the plurality of light sources 111 may be disposed in rows and columns. Accordingly, a plurality of light sources may be disposed so that that a substantially square may be formed by four adjacent light sources. Further, any one light source may be disposed adjacent to the four light sources, and distances between the one light source and the four light sources adjacent thereto may be approximately the same.

As another example, the plurality of light sources may be disposed in a plurality of rows, and a light source belonging to each row may be disposed at a center between two light sources belonging to adjacent rows. Accordingly, the plurality of light sources may be disposed so that an approximately equilateral triangle may be formed by three adjacent light sources. In this case, one light source may be disposed adjacent to six light sources, and distances between the one light source and the six light sources adjacent thereto may be approximately the same.

However, the pattern in which the plurality of light sources 111 are disposed is not limited to the above-described pattern, and the plurality of light sources 111 may be disposed in various patterns so that light may be emitted with uniform luminance.

According to an embodiment, unlike what is shown in FIG. 4, the substrate may be provided in the form of a bar extending in one direction. In this case, the plurality of light sources may be arranged spaced apart along the extending direction of the substrate, thereby forming an array. A plurality of bar-shaped substrates may be provided. The plurality of substrates may be arranged spaced apart from each other along a direction perpendicular to the extending direction of the substrate. For example, the bar-shaped substrates may extend along a horizontal direction, and the plurality of substrates may be arranged spaced apart along a vertical direction.

The light sources 111 may employ an element configured to emit monochromatic light (light having a specific range of wavelengths or light with one peak wavelength, for example, blue light) in various directions when power is supplied.

The substrate 112 may fix the light sources 111 so that a position of each of the light sources 111 is not changed. In addition, the substrate 112 may supply power to each of the light sources 111 to emit light.

The substrate 112 may be formed of a synthetic resin or tempered glass with conductive power supply lines formed therein, or a printed circuit board (PCB) to fix the light sources 111 and supply power to the light sources 111.

The reflective sheet 120 may reflect the light emitted from the plurality of light sources 111 in a forward direction or in a direction close to the forward direction.

In the reflective sheet 120, a plurality of through holes 120a may be formed at positions corresponding to each of the plurality of light sources 111 of the light source module 110. In addition, the light source 111 of the light source module 110 may pass through the through hole 120a and protrude to the front of the reflective sheet 120.

For example, in a process of assembling the reflective sheet 120 and the light source module 110, the plurality of light sources 111 of the light source module 110 may be inserted into the plurality of through holes 120a formed in the reflective sheet 120. Accordingly, the substrate 112 of the light source module 110 may be located behind the reflective sheet 120, but the plurality of light sources 111 of the light source module 110 may be located in front of the reflective sheet 120.

Accordingly, the plurality of light sources 111 may emit light from the front of the reflective sheet 120.

The plurality of light sources 111 may emit light in various directions from the front of the reflective sheet 120. The light may be emitted toward the diffuser plate 130 from the light sources 111 as well as toward the reflective sheet 120 from the light sources 111, and the reflective sheet 120 may reflect the light emitted toward the reflective sheet 120 toward the diffuser plate 130.

The light emitted from the light sources 111 passes through various objects such as the diffuser plate 130, the optical sheet 140, and the like. When the light passes through the diffuser plate 130 and the optical sheet 140, a portion of the incident light may be reflected from the surfaces of the diffuser plate 130 and the optical sheet 140. The reflective sheet 120 may reflect the light reflected by the diffuser plate 130 and the optical sheet 140.

The diffuser plate 130 may be provided in front of the light source module 110 and the reflective sheet 120 and may uniformly diffuse the light emitted from the light source 111 of the light source module 110.

As described above, the plurality of light sources 111 are located in a plurality of places in a rear surface of the backlight unit 100. Although the plurality of light sources 111 may be disposed on the rear surface of the backlight unit 100 at regular intervals, non-uniformity of brightness may occur depending on the positions of the plurality of light sources 111.

The diffuser plate 130 may diffuse the light, which is emitted from the plurality of light sources 111, in the diffuser plate 130 to eliminate the non-uniformity of brightness due to the plurality of light sources 111. In other words, the diffuser plate 130 may uniformly emit non-uniform light of the plurality of light sources 111 toward the front.

The optical sheet 140 may include various sheets to improve brightness. For example, the optical sheet 140 may include a prism sheet 141 and a reflective polarizing sheet 142.

The prism sheet 141 may increase luminance by focusing light. The prism sheet 141 includes a prism pattern having a triangular prism shape, and a plurality of the prism patterns included in the prism sheet 141 are arranged to be adjacent to each other to form a plurality of band shapes. Unlike what is shown in the drawings, the prism sheet 141 may include two or more prism sheets.

The reflective polarization sheet 142 is a type of polarization film, and may transmit a portion of the incident light and reflect another portion of the light to improve luminance. For example, light polarized in the same direction as a predetermined polarization direction of the reflective polarization sheet 142 may be transmitted, and light polarized in a direction different from the polarization direction of the reflective polarization sheet 142 may be reflected. Further, the light reflected by the reflective polarization sheet 142 may be recycled in the backlight unit 100, and such light recycling may allow the luminance of the display apparatus 10 to be improved.

The protective sheet may protect the remaining optical sheets from physical damage. The diffusion sheet may diffuse light to improve luminance uniformity.

FIG. 5 schematically illustrates an example of a light source in a display apparatus according to an embodiment.

Referring to FIG. 5, each of the plurality of light sources 111 may include a light emitting diode (LED) 190 and a multi-layer 200 provided to cover the light emitting diode 190.

According to an embodiment, the multi-layer 200 may include a refractive layer 210 covering the light emitting diode 190, and a quantum dot layer 220 covering the refractive layer 210 and provided to convert the wavelength of light.

The refractive layer 210 may be provided to cover the light emitting diode 190. The refractive layer 210 may be provided to surround an upper surface and four side surfaces of the light emitting diode 190. The refractive layer 210 may be provided to enclose the light emitting diode 190.

The quantum dot layer 220 may be provided to cover the refractive layer 210. The quantum dot layer 220 may be provided to surround the outer surface of the refractive layer 210.

The refractive layer 210 may be provided to have a lower refractive index than a light output layer of the light emitting diode 190. The quantum dot layer 220 may be provided to have a lower refractive index than the refractive layer 210. This will be described later.

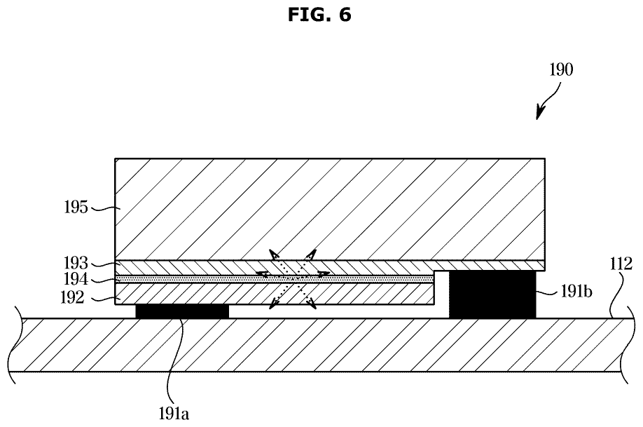

FIG. 6 illustrates a cross-section of an example of a light emitting diode in a display apparatus according to an embodiment.

The light emitting diode 190 may be directly attached to the substrate 112 in a chip-on-board (COB) method. For example, the light source 111 may include the light emitting diode 190 in which a light emitting diode chip or a light emitting diode die is directly attached to the substrate 112 without additional packaging.

The light emitting diode 190 may be manufactured as a flip chip type. When attaching the flip-chip type light emitting diode 190, which is a semiconductor device, to the substrate 112, it is possible to fuse an electrode pattern of the semiconductor device to the substrate 112 as it is, without using an intermediate medium such as a metal lead (wire) or ball grid array (BGA). Because the metal lead (wire) or ball grid array is omitted as mentioned above, it is possible to reduce the size of the light source 111 including the flip-chip type light emitting diode 190.

The light emitting diode 190 may be provided to emit monochromatic light. According to an embodiment, the light emitting diode 190 may be provided to emit blue light. The blue light emitted from the light emitting diode 190 may be converted to white light while passing through the quantum dot layer 220. However, this is not limited thereto, and the light emitting diode may be provided to emit red light or green light.

Referring to FIG. 6, the light emitting diode 190 may include a transparent substrate 195, an n-type semiconductor layer 193, and a p-type semiconductor layer 192. Additionally, a multi quantum well (MQW) layer 194 is formed between the n-type semiconductor layer 193 and the p-type semiconductor layer 192.

The transparent substrate 195 may serve as a base for the pn junction capable of emitting light. The transparent substrate 195 may include, for example, sapphire (Al₂O₃) having a crystal structure similar to that of the semiconductor layers 193 and 192.

A pn junction may be implemented by bonding the n-type semiconductor layer 193 and the p-type semiconductor layer 192. A depletion region may be formed between the n-type semiconductor layer 193 and the p-type semiconductor layer 192. In the depletion region, electrons of the n-type semiconductor layer 193 and holes of the p-type semiconductor layer 192 may recombine. Light may be emitted by the recombination of electrons and holes.

The n-type semiconductor layer 193 may include, for example, n-type gallium nitride (n-type GaN). Additionally, the p-type semiconductor layer 192 may also include, for example, p-type gallium nitride (p-type GaN). The energy band gap of gallium nitride (GaN) is approximately 3.4 eV (electron Volt), which may emit light with a wavelength shorter than approximately 400 nm. Therefore, at the junction of the n-type semiconductor layer 193 and the p-type semiconductor layer 192, blue light (deep blue) or ultraviolet light may be emitted.

The n-type semiconductor layer 193 and the p-type semiconductor layer 192 are not limited to gallium nitride, and various semiconductor materials may be used depending on the required light.

A first electrode 191a of the light emitting diode 190 is in electrical contact with the p-type semiconductor layer 192, and a second electrode 191b is in electrical contact with the n-type semiconductor layer 193. The first electrode 191a and the second electrode 191b may function not only as electrodes but also as reflectors that reflect light.

When a voltage is applied to the light emitting diode 190, holes may be supplied to the p-type semiconductor layer 192 through the first electrode 191a, and electrons may be supplied to the n-type semiconductor layer 193 through the second electrode 191b. The electrons and holes may recombine in the depletion region formed between the p-type semiconductor layer 192 and the n-type semiconductor layer 193. In this case, during the recombination of electrons and holes, the energy of the electrons and holes (for example, kinetic energy and potential energy) may be converted to light energy. In other words, when electrons and holes recombine, light may be emitted.

In this case, the energy band gap of the multi quantum well layer 194 is smaller than the energy gap of the p-type semiconductor layer 192 and/or the n-type semiconductor layer 193. As a result, holes and electrons may each be trapped in the multi quantum well layer 194.

The holes and electrons trapped in the multi quantum well layer 194 may easily recombine with each other in the multi quantum well layer 194. As a result, the light generation efficiency of the light emitting diode 190 may be improved.

In the multi quantum well layer 194, light having a wavelength corresponding to the energy gap of the multi quantum well layer 194 may be emitted. For example, in the multi quantum well layer 194, blue light between 420 nm and 480 nm may be emitted. As such, the multi quantum well layer 194 may correspond to a light emitting layer that emits blue light.

The light generated by the recombination of electrons and holes is not emitted in a specific direction, and as shown in FIG. 6, the light may be emitted in all directions. However, typically, in the case of light emitted from a surface, such as from the multi quantum well layer 194, the intensity of light emitted in a direction perpendicular to the light emitting surface is the greatest, and the intensity of light emitted in a direction parallel to the light emitting surface is the smallest.

According to an embodiment, the light output layer of the light emitting diode 190 may be the transparent substrate 195. The transparent substrate 195 may be provided on the uppermost layer of the light emitting diode 190. The light emitted from the multi quantum well layer 194 may be emitted through the transparent substrate 195 provided on the uppermost layer of the light emitting diode 190. Hereinafter, the transparent substrate 195 of the light emitting diode 190 is referred to as the light output layer 195 of the light emitting diode 190.

According to an embodiment, the transparent substrate 195 may include sapphire material. The transparent substrate 195 may have a first refractive index r1. Therefore, the light output layer 195 of the light emitting diode 190 may have a first refractive index r1. When the light output layer 195 is formed of sapphire material, the first refractive index r1 of the light output layer 195 may be approximately 1.77.

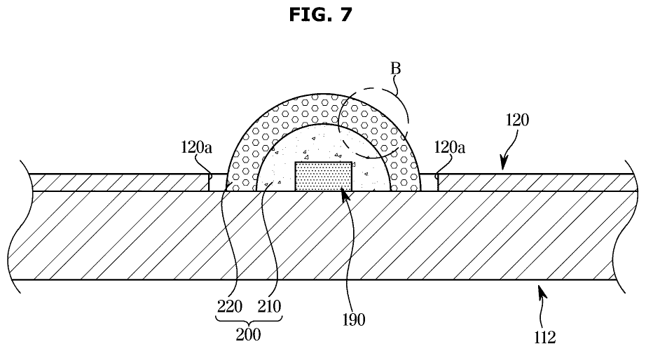

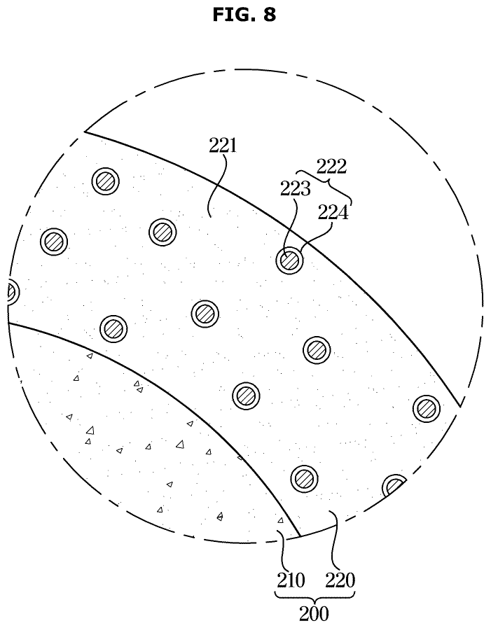

FIG. 7 illustrates an example of a cross-section taken along line A-A′ of FIG. 5. FIG. 8 illustrates an enlarged view of part B of FIG. 7.

Referring to FIGS. 7 and 8, the refractive layer 210 may be provided to surround the upper surface and four side surfaces of the light emitting diode 190. The refractive layer 210 may be formed by dispensing or jetting a liquid resin to cover the upper surface and four side surfaces of the light emitting diode 190 and then curing the resin.

The refractive layer 210 may include at least one of acrylic, silicone, epoxy, and urethane. For example, the refractive layer 210 may be formed by dispensing molten acrylic, silicone, epoxy, or urethane resin in a liquid form on the light emitting diode 190 through a nozzle or the like, and then curing the dispensed acrylic, silicone, epoxy, or urethane. Alternatively, the refractive layer 210 may be formed by placing a mold having a groove corresponding to the shape of the refractive layer 210 on the light emitting diode 190, then filling a liquid resin through an injection port formed in the mold and curing the resin.

The refractive layer 210 may have a second refractive index r2. The second refractive index r2 may be smaller than the first refractive index r1.

The refractive layer 210 may prevent or suppress damage to the light emitting diode 190 due to external mechanical action and/or chemical action.

The quantum dot layer 220 may cover the refractive layer 210. The quantum dot layer 220 may be formed by dispensing or jetting a liquid resin to cover the refractive layer 210 and then curing the resin.

The quantum dot layer 220 may include at least one of acrylic, silicone, epoxy, and urethane. For example, the quantum dot layer 220 may be formed by dispensing molten acrylic, silicone, epoxy, or urethane resin in a liquid form on the refractive layer 210 through a nozzle or the like, and then curing the dispensed acrylic, silicone, epoxy, or urethane. Alternatively, the quantum dot layer 220 may be formed by placing a mold having a groove corresponding to the shape of the quantum dot layer 220 on the refractive layer 210, then filling a liquid resin through an injection port formed in the mold and curing the resin.

The quantum dot layer 220 may have a third refractive index r3. The third refractive index r3 may be smaller than the second refractive index r2. The third refractive index r3 may be greater than 1, which is the refractive index of air.

The quantum dot layer 220 may convert the wavelength of monochromatic light emitted from the light emitting diode 190. The quantum dot layer 220 may convert the monochromatic light to white light by converting the wavelength of the monochromatic light emitted from the light emitting diode 190. To this end, the quantum dot layer 220 may include a plurality of quantum dot particles 222.

For example, the light emitting diode 190 may emit blue light, and the quantum dot layer 220 may convert a portion of the blue light to red light and green light by converting the wavelength of the portion of the blue light. As the portion of the blue light emitted from the light emitting diode 190 is converted to red light and green light while passing through the quantum dot layer 220, the light emitted from the quantum dot layer 220 may become white light. Therefore, the light source module 110 according to the disclosure may include a light source 111 that emits white light.

The quantum dot layer 220 may cover the refractive layer 210. The quantum dot layer 220, like the refractive layer 210, may prevent or suppress damage to the light emitting diode 190 due to external mechanical action and/or chemical action.

The refractive layer 210 may be optically transparent or translucent. Light emitted from the light emitting diode 190 may pass through the refractive layer 210 and the quantum dot layer 220 and be emitted to the outside.

The refractive layer 210 may refract light. Light incident from the light emitting diode 190 to the refractive layer 210 may be refracted by the refractive layer 210 and then emitted outside the refractive layer 210.

The light emitted outside the refractive layer 210 may be incident on the quantum dot layer 220. The quantum dot layer 220 may refract the light. The light incident from the refractive layer 210 to the quantum dot layer 220 may be refracted by the quantum dot layer 220 and then emitted outside the quantum dot layer 220. The light emitted outside the quantum dot layer 220 may be refracted due to the difference in refractive index between the quantum dot layer 220 and air.

Light emitted from the multi quantum well layer 194, which is the light emitting layer of the light emitting diode 190, may be emitted to the outside of the light emitting diode 190 through the transparent substrate 195, which is the light output layer of the light emitting diode 190. Light emitted outside the light emitting diode 190 may be incident on the refractive layer 210 covering the light emitting diode 190. In this case, the light may be refracted due to the difference in refractive index between the light output layer 195 of the light emitting diode 190 and the refractive layer 210. The light emitted outside the refractive layer 210 may be incident on the quantum dot layer 220 covering the refractive layer 210. In this case, the light may be refracted due to the difference in refractive index between the refractive layer 210 and the quantum dot layer 220. The light emitted outside the quantum dot layer 220 may be refracted at the boundary between the quantum dot layer 220 and air due to the difference in refractive index between the quantum dot layer 220 and air.

According to the disclosure, the first refractive index r1 of the light output layer 195, the second refractive index r2 of the refractive layer 210, and the third refractive index r3 of the quantum dot layer 220 may satisfy r1>r2>r3>1 to reduce light loss of the light source 111.

As described above, light emitted from the light emitting diode 190, passing through the refractive layer 210 and the quantum dot layer 220, and then released into air is refracted at the boundary between the light output layer 195 and the refractive layer 210, refracted at the boundary between the refractive layer 210 and the quantum dot layer 220, and refracted at the boundary between the quantum dot layer 220 and air. When the difference in refractive index between the light output layer 195 and the refractive layer 210 is large, or when the difference in refractive index between the refractive layer 210 and the quantum dot layer 220 is large, or when the difference in refractive index between the quantum dot layer 220 and air is large, light loss may increase. Therefore, by providing a gradual decrease in refractive index from the light output layer 195 to the refractive layer 210, to the quantum dot layer 220, and to the air, light loss of the light source 111 may be reduced. In other words, the light output efficiency of the light source 111 may be increased.

According to an embodiment, in order to have the same refractive index difference from the light output layer 195 to air, the difference between the first refractive index r1 and the second refractive index r2, the difference between the second refractive index r2 and the third refractive index r3, and the difference between the third refractive index r3 and the refractive index of air, which is 1, may be set to (r1−1)/3.

For example, when the first refractive index r1 of the light output layer 195 is approximately 1.77, the second refractive index r2 may be approximately 1.51, which is 1.77−(1.77−1)/3, and the third refractive index r3 may be approximately 1.26, which is 1.77−(1.77−1)*2/3. However, this is merely an example, and the second refractive index r2 may be r1−(r1−1)/3±0.3. The third refractive index r3 may be r1−(r1−1)*2/3±0.3. In this case, the third refractive index r3 needs to be greater than 1.

The quantum dot layer 220 may convert monochromatic light to white light by converting the wavelength of monochromatic light emitted from the light source 111. As described above, the quantum dot layer 220 may include a plurality of quantum dot (QD) particles 222 that convert the wavelength of light.

For example, the light emitting diode 190 may emit blue light, and the quantum dot layer 220 may convert a portion of the blue light to red light and green light by converting the wavelength of the portion of the blue light. As a portion of blue light emitted from the light emitting diode 190 is converted to red light and green light while passing through the quantum dot layer 220, the light emitted through the quantum dot layer 220 may become white light.

Referring to FIG. 8, the quantum dot layer 220 may include a plurality of quantum dot particles 222. The quantum dot layer 220 may include a resin 221 including at least one of acrylic, silicone, epoxy, and urethane, and a plurality of quantum dot particles 222 dispersed and arranged within the resin 221.

The resin 221 may be formed by dispensing or jetting a molten acrylic, silicone, epoxy, or urethane resin in a liquid form on the refractive layer 210 through a nozzle or the like and then curing the resin, or may be formed through a mold.

Each of the plurality of quantum dot particles 222 may include a quantum dot 223 and a quantum dot coating layer 224 surrounding the quantum dot 223. The quantum dot coating layer 224 may be formed by coating the quantum dot 223 with an inorganic film. The quantum dot coating layer 224 may include at least one of silicon dioxide (SiO₂), aluminum oxide (Al₂O₃), and hafnium oxide (HfO₂). The quantum dot coating layer 224 may be formed through at least one of an atmospheric laser treatment (ALT) method, a physical vapor deposition (PVD) method, and a chemical vapor deposition (CVD) method. Through this, the quantum dot particles 222 including the quantum dot coating layer 224 may have high durability and corrosion resistance.

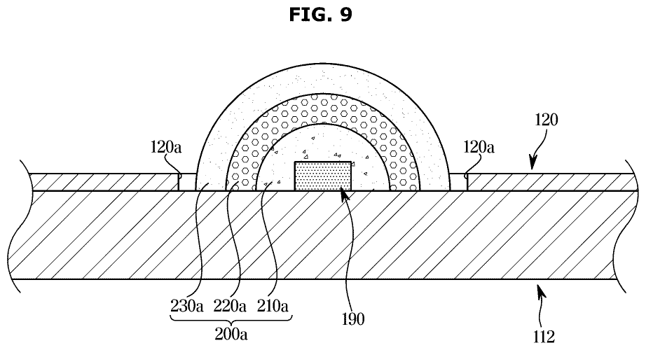

FIG. 9 illustrates an example of a cross-section taken along line A-A′ of FIG. 5.

Referring to FIG. 9, a light source 111 according to an embodiment may include a multi-layer 200a.

The multi-layer 200a may include a first refractive layer 210a covering the light emitting diode 190, a quantum dot layer 220a covering the first refractive layer 210a, and a second refractive layer 230a covering the quantum dot layer 220a.

The first refractive layer 210a may be provided to surround the upper surface and four side surfaces of the light emitting diode 190. The first refractive layer 210a may be formed by dispensing or jetting a liquid resin to cover the upper surface and four side surfaces of the light emitting diode 190 and then curing the resin.

The first refractive layer 210a may include at least one of acrylic, silicone, epoxy, and urethane. For example, the first refractive layer 210a may be formed by dispensing a molten acrylic, silicone, epoxy, or urethane resin in a liquid form on the light emitting diode 190 through a nozzle or the like, and then curing the dispensed acrylic, silicone, epoxy, or urethane to form the first refractive layer 210a. Alternatively, the first refractive layer 210a may be formed by placing a mold having a groove corresponding to the shape of the first refractive layer 210a on the light emitting diode 190, then filling a liquid resin through an injection port formed in the mold and curing the resin.

The first refractive layer 210a may have a second refractive index r2. The second refractive index r2 may be smaller than the first refractive index r1 of the light output layer 195.

The first refractive layer 210a may prevent or suppress damage to the light emitting diode 190 due to external mechanical action and/or chemical action.

The quantum dot layer 220a may cover the first refractive layer 210a. The quantum dot layer 220a may include at least one of acrylic, silicone, epoxy, and urethane. For example, the quantum dot layer 220a may be formed by dispensing a molten acrylic, silicone, epoxy, or urethane resin in a liquid form on the first refractive layer 210a through a nozzle or the like, and then curing the dispensed acrylic, silicone, epoxy, or urethane to form the quantum dot layer 220a. Alternatively, the quantum dot layer 220a may be formed by placing a mold having a groove corresponding to the shape of the quantum dot layer 220a on the first refractive layer 210a, then filling a liquid resin through an injection port formed in the mold and curing the resin.

The quantum dot layer 220a may have a third refractive index r3. The third refractive index r3 may be smaller than the second refractive index r2.

The quantum dot layer 220a may convert the wavelength of monochromatic light emitted from the light emitting diode 190. The quantum dot layer 220a may convert monochromatic light to white light by converting the wavelength of monochromatic light emitted from the light emitting diode 190. To this end, the quantum dot layer 220a may include a plurality of quantum dot particles 222.

The second refractive layer 230a may cover the quantum dot layer 220a. The second refractive layer 230a may include at least one of acrylic, silicone, epoxy, and urethane. For example, the second refractive layer 230a may be formed by dispensing a molten acrylic, silicone, epoxy, or urethane resin in a liquid form on the quantum dot layer 220a through a nozzle or the like, and then curing the dispensed acrylic, silicone, epoxy, or urethane to form the second refractive layer 230a. Alternatively, the second refractive layer 230a may be formed by placing a mold having a groove corresponding to the shape of the second refractive layer 230a on the quantum dot layer 220a, then filling a liquid resin through an injection port formed in the mold and curing the resin.

The second refractive layer 230a may have a fourth refractive index r4. The fourth refractive index r4 may be smaller than the third refractive index r3. The fourth refractive index r4 may be greater than 1, which is the refractive index of air.

The first refractive layer 210a and the second refractive layer 230a may be optically transparent or translucent. Light emitted from the light emitting diode 190 may pass through the first refractive layer 210a, the quantum dot layer 220a, and the second refractive layer 230a and be emitted to the outside.

The first refractive layer 210a may refract light. Light incident from the light emitting diode 190 to the first refractive layer 210a may be refracted by the first refractive layer 210a and then emitted outside the first refractive layer 210a.

Light emitted outside the first refractive layer 210a may be incident on the quantum dot layer 220a. The quantum dot layer 220a may refract the light. The light incident from the first refractive layer 210a to the quantum dot layer 220a may be refracted by the quantum dot layer 220a and then emitted outside the quantum dot layer 220a. The light emitted outside the quantum dot layer 220a may be incident on the second refractive layer 230a.

The light incident on the second refractive layer 230a may be refracted due to the difference in refractive index between the quantum dot layer 220a and the second refractive layer 230a. The light emitted outside the second refractive layer 230a may be refracted due to the difference in refractive index between the second refractive layer 230a and air.

Light emitted from the multi quantum well layer 194, which is the light emitting layer of the light emitting diode 190, may be emitted to the outside of the light emitting diode 190 through the transparent substrate 195, which is the light output layer of the light emitting diode 190. Light emitted outside the light emitting diode 190 may be incident on the first refractive layer 210a covering the light emitting diode 190. In this case, the light may be refracted due to the difference in refractive index between the light output layer 195 of the light emitting diode 190 and the first refractive layer 210a. The light emitted outside the first refractive layer 210a may be incident on the quantum dot layer 220a covering the first refractive layer 210a. In this case, the light may be refracted due to the difference in refractive index between the first refractive layer 210a and the quantum dot layer 220a. The light emitted outside the quantum dot layer 220a may be incident on the second refractive layer 230a. In this case, the light may be refracted due to the difference in refractive index between the quantum dot layer 220a and the second refractive layer 230a. The light emitted outside the second refractive layer 230a may be refracted at the boundary between the second refractive layer 230a and air due to the difference in refractive index between the second refractive layer 230a and air.

According to the disclosure, the first refractive index r1 of the light output layer 195, the second refractive index r2 of the first refractive layer 210a, the third refractive index r3 of the quantum dot layer 220a, and the fourth refractive index r4 of the second refractive layer 230a may satisfy r1>r2>r3>r4>1 to reduce light loss of the light source 111.

As described above, light emitted from the light emitting diode 190, passing through the first refractive layer 210a, the quantum dot layer 220a, the second refractive layer 230a, and then into air is refracted at the boundary between the light output layer 195 and the first refractive layer 210a, refracted at the boundary between the first refractive layer 210a and the quantum dot layer 220a, refracted at the boundary between the quantum dot layer 220a and the second refractive layer 230a, and refracted at the boundary between the second refractive layer 230a and air. When the difference in refractive index between the light output layer 195 and the first refractive layer 210a is large, or when the difference in refractive index between the first refractive layer 210a and the quantum dot layer 220a is large, or when the difference in refractive index between the quantum dot layer 220a and the second refractive layer 230a is large, or when the difference in refractive index between the second refractive layer 230a and air is large, light loss may increase. Therefore, by providing a gradual decrease in refractive index from the light output layer 195 to the first refractive layer 210a, to the quantum dot layer 220a, to the second refractive layer 230a, and to air, light loss of the light source 111 may be reduced. In other words, the light output efficiency of the light source 111 may be increased.

According to an embodiment, in order to have the same refractive index difference from the light output layer 195 to air, the difference between the first refractive index r1 and the second refractive index r2, the difference between the second refractive index r2 and the third refractive index r3, the difference between the third refractive index r3 and the fourth refractive index r4, and the difference between the fourth refractive index r4 and the refractive index of air, which is 1, may be set to (r1−1)/4.

For example, when the first refractive index r1 of the light output layer 195 is approximately 1.77, the second refractive index r2 may be approximately 1.58, which is 1.77−(1.77−1)/4, and the third refractive index r3 may be approximately 1.39, which is 1.77−(1.77−1)*2/4. The fourth refractive index r4 may be approximately 1.19, which is 1.77−(1.77−1)*3/4. However, this is merely an example, and the second refractive index r2 may be r1−(r1−1)/4±0.3. The third refractive index r3 may be r1−(r1−1)*2/4±0.3. The fourth refractive index r4 may be r1−(r1−1)*3/4±0.3. In this case, the fourth refractive index r4 needs to be greater than 1.

The quantum dot layer 220a may convert monochromatic light to white light by converting the wavelength of monochromatic light emitted from the light source 111. As described above, the quantum dot layer 220a may include a plurality of quantum dot (QD) particles 222 that convert the wavelength of light.

For example, the light emitting diode 190 may emit blue light, and the quantum dot layer 220a may convert a portion of the blue light to red light and green light by converting the wavelength of the portion of the blue light. As a portion of the blue light emitted from the light emitting diode 190 is converted to red light and green light while passing through the quantum dot layer 220a, the light emitted through the quantum dot layer 220a may become white light.

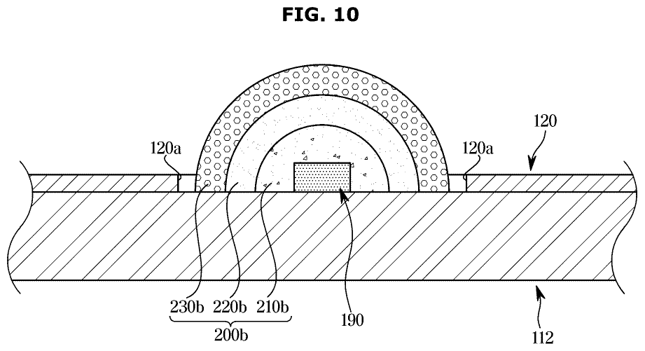

FIG. 10 illustrates an example of a cross-section along line A-A′ of FIG. 5.

Referring to FIG. 10, a light source 111 according to an embodiment may include a multi-layer 200b.

The multi-layer 200b may include a first refractive layer 210b covering the light emitting diode 190, a second refractive layer 220b covering the first refractive layer 210a, and a quantum dot layer 230b covering the second refractive layer 220b.

The first refractive layer 210b may be provided to surround the upper surface and four side surfaces of the light emitting diode 190. The first refractive layer 210b may be formed by dispensing or jetting a liquid resin to cover the upper surface and four side surfaces of the light emitting diode 190 and then curing the resin.

The first refractive layer 210b may include at least one of acrylic, silicone, epoxy, and urethane. For example, the first refractive layer 210b may be formed by dispensing a molten acrylic, silicone, epoxy, or urethane resin in liquid form on the light emitting diode 190 through a nozzle or the like, and then curing the dispensed acrylic, silicone, epoxy, or urethane to form the first refractive layer 210b. Alternatively, the first refractive layer 210b may be formed by placing a mold having a groove corresponding to the shape of the first refractive layer 210b on the light emitting diode 190, then filling a liquid resin through an injection port formed in the mold and curing the resin.

The first refractive layer 210b may have a second refractive index r2. The second refractive index r2 may be smaller than the first refractive index r1 of the light output layer 195.

The first refractive layer 210b may prevent or suppress damage to the light emitting diode 190 due to external mechanical action and/or chemical action.

The second refractive layer 220b may cover the first refractive layer 210b. The second refractive layer 220b may include at least one of acrylic, silicone, epoxy, and urethane. For example, the second refractive layer 220b may be formed by dispensing a molten acrylic, silicone, epoxy, or urethane resin in a liquid form on the first refractive layer 210b through a nozzle or the like, and then curing the dispensed acrylic, silicone, epoxy, or urethane to form the second refractive layer 220b. Alternatively, the second refractive layer 220b may be formed by placing a mold having a groove corresponding to the shape of the second refractive layer 220b on the first refractive layer 210b, then filling a liquid resin through an injection port formed in the mold and curing the resin.

The second refractive layer 220b may have a third refractive index r3. The third refractive index r3 may be smaller than the second refractive index r2.

The quantum dot layer 230b may cover the second refractive layer 220b. The quantum dot layer 230b may include at least one of acrylic, silicone, epoxy, and urethane. For example, the quantum dot layer 230b may be dispensing a molten acrylic, silicone, epoxy, or urethane resin in a liquid form on the second refractive layer 220b through a nozzle or the like, and then curing the dispensed acrylic, silicone, epoxy, or urethane to form the quantum dot layer 230b. Alternatively, the quantum dot layer 230b may be formed by placing a mold having a groove corresponding to the shape of the quantum dot layer 230b on the second refractive layer 220b, then filling a liquid resin through an injection port formed in the mold and curing the resin.

The quantum dot layer 230b may convert the wavelength of monochromatic light emitted from the light emitting diode 190. The quantum dot layer 230b may convert monochromatic light to white light by converting the wavelength of monochromatic light emitted from the light emitting diode 190. To this end, the quantum dot layer 230b may include a plurality of quantum dot particles 222.

The quantum dot layer 230b may have a fourth refractive index r4. The fourth refractive index r4 may be smaller than the third refractive index r3. The fourth refractive index r4 may be greater than 1, which is the refractive index of air.

The first refractive layer 210b and the second refractive layer 220b may be optically transparent or translucent. Light emitted from the light emitting diode 190 may pass through the first refractive layer 210b, the second refractive layer 220b, and the quantum dot layer 230b and be emitted to the outside.

Light emitted from the multi quantum well layer 194, which is the light emitting layer of the light emitting diode 190, may be emitted to the outside of the light emitting diode 190 through the transparent substrate 195, which is the light output layer of the light emitting diode 190. Light emitted outside the light emitting diode 190 may be incident on the first refractive layer 210b covering the light emitting diode 190. In this case, the light may be refracted due to the difference in refractive index between the light output layer 195 of the light emitting diode 190 and the first refractive layer 210b. The light emitted outside the first refractive layer 210b may be incident on the second refractive layer 220b covering the first refractive layer 210b. In this case, the light may be refracted due to the difference in refractive index between the first refractive layer 210b and the second refractive layer 220b. The light emitted outside the second refractive layer 220b may be incident on the quantum dot layer 230b. In this case, the light may be refracted due to the difference in refractive index between the second refractive layer 220b and the quantum dot layer 230b. The light emitted outside the quantum dot layer 230b may be refracted at the boundary between the quantum dot layer 230b and air due to the difference in refractive index between the quantum dot layer 230b and air.

According to the disclosure, the first refractive index r1 of the light output layer 195, the second refractive index r2 of the first refractive layer 210a, the third refractive index r3 of the second refractive layer 220b, and the fourth refractive index r4 of the quantum dot layer 230b may satisfy r1>r2>r3>r4>1 to reduce light loss of the light source 111.

As described above, light emitted from the light emitting diode 190, passing through the first refractive layer 210b, the second refractive layer 220b, the quantum dot layer 230b, and then released into air is refracted at the boundary between the light output layer 195 and the first refractive layer 210b, refracted at the boundary between the first refractive layer 210a and the second refractive layer 220b, refracted at the boundary between the second refractive layer 220b and the quantum dot layer 230b, and refracted at the boundary between the quantum dot layer 230b and air. When the difference in refractive index between the light output layer 195 and the first refractive layer 210b is large, or when the difference in refractive index between the first refractive layer 210b and the second refractive layer 220b is large, or when the difference in refractive index between the second refractive layer 220b and the quantum dot layer 230b is large, or when the difference in refractive index between the quantum dot layer 230b and air is large, light loss may increase. Therefore, by providing a gradual decrease in refractive index from the light output layer 195 to the first refractive layer 210b, the second refractive layer 220b, the quantum dot layer 230b, and air, light loss of the light source 111 may be reduced. In other words, the light output efficiency of the light source 111 may be increased.

According to an embodiment, in order to have the same refractive index difference from the light output layer 195 to air, the difference between the first refractive index r1 and the second refractive index r2, the difference between the second refractive index r2 and the third refractive index r3, the difference between the third refractive index r3 and the fourth refractive index r4, and the difference between the fourth refractive index r4 and the refractive index of air, which is 1, may be set to (r1-1)/4.

For example, when the first refractive index r1 of the light output layer 195 is approximately 1.77, the second refractive index r2 may be approximately 1.58, which is 1.77−(1.77−1)/4, and the third refractive index r3 may be approximately 1.39, which is 1.77−(1.77−1)*2/4. The fourth refractive index r4 may be approximately 1.19, which is 1.77−(1.77−1)*3/4. However, this is merely an example, and the second refractive index r2 may be r1−(r1−1)/4±0.3. The third refractive index r3 may be r1−(r1−1)*2/4±0.3. The fourth refractive index r4 may be r1−(r1−1)*3/4±0.3. In this case, the fourth refractive index r4 needs to be greater than 1.

The quantum dot layer 230b may convert monochromatic light to white light by converting the wavelength of monochromatic light emitted from the light source 111. As described above, the quantum dot layer 230b may include a plurality of quantum dot (QD) particles 222 that convert the wavelength of light.

For example, the light emitting diode 190 may emit blue light, and the quantum dot layer 230b may convert a portion of the blue light to red light and green light by converting the wavelength of the portion of the blue light. As a portion of the blue light emitted from the light emitting diode 190 is converted to red light and green light while passing through the quantum dot layer 230b, the light emitted through the quantum dot layer 230b may become white light.

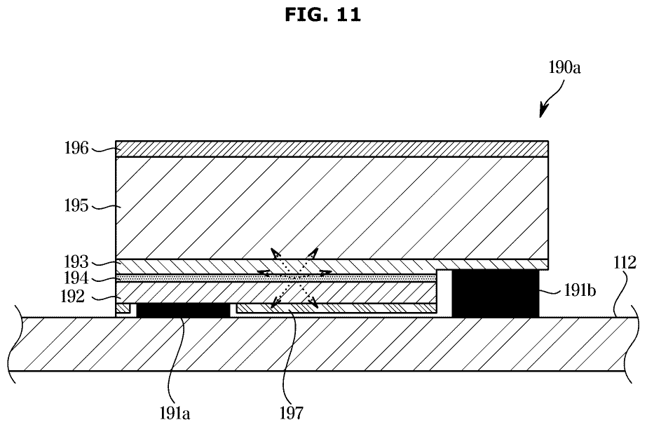

FIG. 11 illustrates a cross-section of an example of a light emitting diode in a display apparatus according to an embodiment.

Referring to FIG. 11, a light emitting diode 190a may include a transparent substrate 195, an n-type semiconductor layer 193, and a p-type semiconductor layer 192. Additionally, a multi quantum well (MQW) layer 194 is formed between the n-type semiconductor layer 193 and the p-type semiconductor layer 192.

The transparent substrate 195 may serve as a base for the pn junction capable of emitting light. The transparent substrate 195 may include, for example, sapphire (Al₂O₃) having a crystal structure similar to that of the semiconductor layers 193 and 192.

A pn junction may be implemented by bonding the n-type semiconductor layer 193 and the p-type semiconductor layer 192. A depletion region may be formed between the n-type semiconductor layer 193 and the p-type semiconductor layer 192. In the depletion region, electrons of the n-type semiconductor layer 193 and holes of the p-type semiconductor layer 192 may recombine. Light may be emitted by the recombination of electrons and holes.

The n-type semiconductor layer 193 may include, for example, n-type gallium nitride (n-type GaN). Additionally, the p-type semiconductor layer 192 may also include, for example, p-type gallium nitride (p-type GaN). The energy band gap of gallium nitride (GaN) is approximately 3.4 eV (electron Volt), which may emit light with a wavelength shorter than approximately 400 nm. Therefore, at the junction of the n-type semiconductor layer 193 and the p-type semiconductor layer 192, blue light (deep blue) or ultraviolet light may be emitted.

The n-type semiconductor layer 193 and the p-type semiconductor layer 192 are not limited to gallium nitride, and various semiconductor materials may be used depending on the required light.

A first electrode 191a of the light emitting diode 190a is in electrical contact with the p-type semiconductor layer 192, and a second electrode 191b is in electrical contact with the n-type semiconductor layer 193. The first electrode 191a and the second electrode 191b may function not only as electrodes but also as reflectors that reflect light.

When a voltage is applied to the light emitting diode 190a, holes may be supplied to the p-type semiconductor layer 192 through the first electrode 191a, and electrons may be supplied to the n-type semiconductor layer 193 through the second electrode 191b. The electrons and holes may recombine in the depletion region formed between the p-type semiconductor layer 192 and the n-type semiconductor layer 193. In this case, during the recombination of electrons and holes, the energy of the electrons and holes (for example, kinetic energy and potential energy) may be converted to light energy. In other words, when electrons and holes recombine, light may be emitted.

In this case, the energy band gap of the multi quantum well layer 194 is smaller than the energy gap of the p-type semiconductor layer 192 and/or the n-type semiconductor layer 193. As a result, holes and electrons may each be trapped in the multi quantum well layer 194.

The holes and electrons trapped in the multi quantum well layer 194 may easily recombine with each other in the multi quantum well layer 194. As a result, the light generation efficiency of the light emitting diode 190a may be improved.

In the multi quantum well layer 194, light having a wavelength corresponding to the energy gap of the multi quantum well layer 194 may be emitted. For example, in the multi quantum well layer 194, blue light between 420 nm and 480 nm may be emitted. As such, the multi quantum well layer 194 may correspond to a light emitting layer that emits blue light.

The light generated by the recombination of electrons and holes is not emitted in a specific direction, and as shown in FIG. 11, the light may be emitted in all directions. However, typically, in the case of light emitted from a surface such as from the multi quantum well layer 194, the intensity of light emitted in a direction perpendicular to the light emitting surface is the greatest, and the intensity of light emitted in a direction parallel to the light emitting surface is the smallest.

According to an embodiment, a first reflective layer 196 may be provided on the outside of the transparent substrate 195 (an upper side of the transparent substrate in the drawing). The first reflective layer 196 may be disposed on an upper side of the light emitting layer 194.

According to an embodiment, a second reflective layer 197 may be provided on the outside of the p-type semiconductor layer 192 (a lower side of the p-type semiconductor layer in the drawing). The transparent substrate 195, the n-type semiconductor layer 193, the multi quantum well layer 194, and the p-type semiconductor layer 192 may be disposed between the first reflective layer 196 and the second reflective layer 197.

The first reflective layer 196 and the second reflective layer 197 may each reflect some portion of incident light and allow another portion of the incident light to pass through.

For example, the first reflective layer 196 and the second reflective layer 197 may reflect light having wavelengths included in a specific wavelength range and allow light having wavelengths outside the specific wavelength range to pass through. For example, the first reflective layer 196 and the second reflective layer 197 may reflect blue light having wavelengths between 420 nm and 480 nm, which is emitted from the multi quantum well layer 194.

Additionally, the first reflective layer 196 and the second reflective layer 197 may reflect incident light having a specific incident angle and allow light outside the specific incident angle to pass through. As such, the first reflective layer 196 and the second reflective layer 197 may be a distributed Bragg reflector (DBR) layer formed by stacking materials with different refractive indices to have various reflectances according to the incident angle.

For example, the first reflective layer 196 may reflect light incident at a small incident angle and allow light incident at a large incident angle to pass through. Additionally, the second reflective layer 197 may reflect or allow light incident at a small incident angle to pass through and reflect light incident at a large incident angle. Here, the incident light may be blue light having wavelengths between 420 nm and 480 nm.

The first reflective layer 196 and the second reflective layer 197 may each be provided by stacking two materials having different refractive indices. For example, the first reflective layer 196 may be provided by stacking silicon dioxide (SiO₂) and titanium dioxide (TiO₂). Similarly, the second reflective layer 197 may be provided by stacking silicon dioxide (SiO₂) and titanium dioxide (TiO₂).

According to an embodiment, the light output layer of the light emitting diode 190 may be the first reflective layer 196. The first reflective layer 196 may be provided on the uppermost layer of the light emitting diode 190. Light emitted from the multi quantum well layer 194 may be emitted through the first reflective layer 196 provided on the uppermost layer of the light emitting diode 190. Hereinafter, the first reflective layer 196 of the light emitting diode 190 is referred to as the light output layer 196 of the light emitting diode 190.

According to an embodiment, the first reflective layer 196 may be provided by stacking silicon dioxide (SiO₂) and titanium dioxide (TiO₂). The first reflective layer 196 may have a first refractive index r1. Therefore, the light output layer 196 of the light emitting diode 190 may have a first refractive index r1. When the light output layer 196 is provided by stacking silicon dioxide (SiO₂) and titanium dioxide (TiO₂), the first refractive index r1 of the light output layer 196 may be determined between approximately 1.45, which is the refractive index of silicon dioxide (SiO₂), and approximately 2.55, which is the refractive index of titanium dioxide (TiO₂). The first refractive index r1 of the light output layer 196 may be determined according to the thickness of the silicon dioxide (SiO₂) layer and the titanium dioxide (TiO₂) layer.

According to an embodiment, the light source 111 may include the light emitting diode 190a including the first reflective layer 196 and the second reflective layer 197. Therefore, the multi-layer 200 shown in FIG. 7 may be applied to the light emitting diode 190a shown in FIG. 11. Similarly, the multi-layer 200a shown in FIG. 9 may be applied to the light emitting diode 190a. Additionally, the multi-layer 200b shown in FIG. 10 may be applied to the light emitting diode 190a.

A display apparatus according to an embodiment includes a liquid crystal panel 20 and a backlight unit 100 providing light to the liquid crystal panel. The backlight unit includes: a substrate 112; a light emitting diode 190 mounted on the substrate and including a light output layer 195 having a first refractive index r1; a refractive layer 210 covering the light emitting diode and having a second refractive index r2 lower than the first refractive index; and a quantum dot layer 220 covering the refractive layer, provided to convert the wavelength of light emitted from the light emitting diode, and having a third refractive index r3 lower than the second refractive index.

The third refractive index of the quantum dot layer may be greater than 1.

The second refractive index may be r1−(r1−1)/3±0.3.

The third refractive index may be r1−(r1−1)*2/3±0.3.

The refractive layer may be a first refractive layer 210a.

The display apparatus may further include a second refractive layer 230a covering the quantum dot layer 220a and having a fourth refractive index r4 lower than the third refractive index.

The second refractive index may be r1−(r1−1)/4±0.3.

The third refractive index may be r1−(r1−1)*2/4±0.3.

The fourth refractive index may be r1−(r1−1)*3/4±0.3.

The quantum dot layer may include a resin 221 configured to include at least one of acrylic, silicone, epoxy, and urethane.

The quantum dot layer may include a plurality of quantum dot particles 222 dispersed and arranged within the resin.

Each of the plurality of quantum dot particles may include a quantum dot 223 and a quantum dot coating layer 223 surrounding the quantum dot.

The quantum dot coating layer may include at least one of SiO₂, Al₂O₃, and

### HfO₂.

The thickness of the quantum dot coating layer 223 may be 1 nm to 1 μm.

The refractive layer may include at least one of acrylic, silicone, epoxy, and urethane.

The light output layer of the light emitting diode may be a transparent substrate 195 of the light emitting diode or a reflective layer 196 provided on the transparent substrate.

The light emitting diode may be mounted on the substrate in a chip-on-board (COB) manner.

A display apparatus according to an embodiment includes a liquid crystal panel 20 and a backlight unit 100 providing light to the liquid crystal panel. The backlight unit 100 includes: a substrate 112; a light emitting diode 190 mounted on the substrate and including a light output layer 195 having a first refractive index r1; a first refractive layer 210b covering the light emitting diode and having a second refractive index r2 lower than the first refractive index; a second refractive layer 220b covering the first refractive layer and having a third refractive index r3 lower than the second refractive index; and a quantum dot layer 230b covering the second refractive layer, configured to convert the wavelength of light emitted from the light emitting diode, and having a fourth refractive index r4 lower than the third refractive index.

The second refractive index may be r1−(r1−1)/4±0.3.

The third refractive index may be r1−(r1−1)*2/4±0.3.

The fourth refractive index may be r1−(r1−1)*3/4±0.3.

The quantum dot layer may include a resin 221 including at least one of acrylic, silicone, epoxy, and urethane.

The quantum dot layer may include a plurality of quantum dot particles 222 dispersed and arranged within the resin.

Each of the plurality of quantum dot particles may include a quantum dot 223 and a quantum dot coating layer 223 surrounding the quantum dot.

The quantum dot coating layer may be configured to include at least one of SiO₂, Al₂O₃, and HfO₂.

The thickness of the quantum dot coating layer 223 may be 1 nm to 1 μm.

The first refractive layer and the second refractive layer may be configured to include at least one of acrylic, silicone, epoxy, and urethane.

According to the concept of the present disclosure, a backlight unit including a light source with improved light output efficiency, and a display apparatus having the same can be provided.

Although embodiments of the present disclosure have been described with reference to the accompanying drawings, those skilled in the art will appreciate that the concepts may be embodied in different forms without departing from the scope and spirit of the disclosure, and should not be construed as limited to the embodiments set forth herein.

What is claimed is:

1. A display apparatus comprising:
a liquid crystal panel; and
a backlight configured to provide light to the liquid crystal panel,
wherein the backlight comprises:
a substrate;
a light emitting diode provided on the substrate, the light emitting diode comprising a light output layer having a first refractive index, r1;
a refractive layer covering the light emitting diode and having a second refractive index, r2, that is lower than the first refractive index; and
a quantum dot layer covering the refractive layer, configured to convert a wavelength of light emitted from the light emitting diode, the quantum dot layer having a third refractive index, r3, that is lower than the second refractive index.

2. The display apparatus of claim 1, wherein the third refractive index of the quantum dot layer is greater than 1.

3. The display apparatus of claim 1, wherein the second refractive index is r1−(r1−1)/3±0.3.

4. The display apparatus of claim 1, wherein the third refractive index is r1−(r1−1)*2/3±0.3.

5. The display apparatus of claim 1, wherein the refractive layer is a first refractive layer, further comprising: a second refractive layer covering the quantum dot layer and having a fourth refractive index, r4, that is lower than the third refractive index.

6. The display apparatus of claim 5, wherein the second refractive index is r1−(r1−1)/4±0.3.

7. The display apparatus of claim 5, wherein the third refractive index is r1−(r1−1)*2/4±0.3.

8. The display apparatus of claim 5, wherein the fourth refractive index is r1−(r1−1)*3/4=0.3.

9. The display apparatus of claim 1, wherein the quantum dot layer comprises:
a resin including at least one of acrylic, silicone, epoxy, or urethane; and
a plurality of quantum dot particles dispersed within the resin.

10. The display apparatus of claim 9, wherein each of the plurality of quantum dot particles comprises a quantum dot and a quantum dot coating layer surrounding the quantum dot, wherein the quantum dot coating layer includes at least one of SiO₂, Al₂O₃, or HfO₂.

11. The display apparatus of claim 10, wherein a thickness of the quantum dot coating layer is 1 nm to 1 μm.

12. The display apparatus of claim 1, wherein the refractive layer includes at least one of acrylic, silicone, epoxy, or urethane.

13. The display apparatus of claim 1, wherein the light output layer of the light emitting diode is a transparent substrate of the light emitting diode or a reflective layer provided on the transparent substrate.

14. The display apparatus of claim 1, wherein the light emitting diode is provided on the substrate in a chip-on-board manner.
